(19) United States
(12) Patent Application Publication
(10) Pub. No.: US 2023/0022720 A1
(43) Pub. Date: Jan. 26, 2023

(54) APPARATUS FOR TREATING SUBSTRATE

(71) Applicant: SEMES CO., LTD., Cheonan-si (KR)

(72) Inventors: Young Je UM, Busan (KR); Wan Jae PARK, Hwaseong-si (KR); Jun Taek KOO, Seoul (KR)

(73) Assignee: SEMES CO., LTD., Cheonan-si (KR)

(21) Appl. No.: 17/868,048

(22) Filed: Jul. 19, 2022

(30) Foreign Application Priority Data
Jul. 22, 2021 (KR) 10-2021-0096242

(51) Int. Cl. H01J 37/32; H01L 21/683

(52) U.S. Cl. CPC H01J 37/32568; H01J 37/32422; H01J 37/3244; H01L 21/6833

(57) ABSTRACT

The inventive concept provides a substrate treating apparatus. The substrate treating apparatus includes a housing defining a treating space; a chuck supporting a substrate at the treating space and providing a bottom electrode for generating a plasma at the treating space; a top electrode; and an ion blocker positioned between the top electrode and the treating space.

### CROSS-REFERENCE TO RELATED APPLICATIONS

A claim for priority under 35 U.S.C. § 119 is made to Korean Patent Application No. 10-2021-0096242 filed on Jul. 22, 2021, in the Korean Intellectual Property Office, the entire contents of which are hereby incorporated by reference.

### TECHNICAL FIELD

Embodiments of the inventive concept described herein relate to a substrate treating apparatus.

### BACKGROUND

In a fabrication of a semiconductor device, a desired pattern is formed on a substrate such as a wafer through various processes such as a photolithography, an etching, an ashing, an ion implantation, and a thin film deposition. For each of the processes, various treating liquids and treating gases are used, and particles and process by-products are generated during a process.

FIG. 1 illustrates illustrating a state of the substrate on which a treating process has been partially performed. Referring to FIG. 1, a film L may be formed on the substrate W on which the treating process has been partially performed, and a hole H (also referred to as a pattern) penetrating the film L through a treatment such as an etching may be formed. The film L may be made of a material such as a nitride, an oxide, or a metal (e.g., tungsten).

In the process of treating the substrate W, various impurities may be attached to the substrate W. For example, the impurities may be organic impurities OP including a carbon and inorganic impurities IOP not including a carbon. The organic impurities OP and the inorganic impurities IOP may both be attached on the substrate W, and in some cases, the organic impurities OP may be attached. In addition, these impurities may be attached to an inside of the hole H formed on the substrate W.

In general, a chemical is supplied onto the substrate W to remove such impurities attached to the hole H. Recently, as an aspect ratio (AR) of the hole H is increased due to a densification of a pattern formed on the substrate W, the chemical may not properly permeate into the hole H, and thus the impurities attached to the substrate W may not be appropriately removed.

### SUMMARY

Embodiments of the inventive concept provide a substrate treating apparatus for efficiently treating a substrate.

Embodiments of the inventive concept provide a substrate treating apparatus for effectively removing impurities attached to the substrate.

Embodiments of the inventive concept provide a substrate treating apparatus for improving a removing efficiency of impurities attached to a substrate by differentiating a treating mode according to a type of the impurities attached to the substrate.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a housing defining a treating space; a chuck supporting a substrate at the treating space and providing a bottom electrode for generating a plasma at the treating space; a top electrode; and an ion blocker positioned between the top electrode and the treating space.

In an embodiment, the ion blocker is grounded and removes an ion from the plasma generated at a plasma space which is a space between the top electrode and the ion blocker.

In an embodiment, the substrate treating apparatus further includes a bottom power module applying a power to the bottom electrode; a top power module applying a power to the top electrode; and a gas supply unit supplying a process gas for exciting to the plasma by the bottom electrode or the top electrode.

In an embodiment, the gas supply unit includes: a first gas supply unit for supplying the process gas to the treating space; and a second gas supply unit for supplying the process gas to the plasma space which is a space between the ion blocker and the top electrode.

In an embodiment, the substrate treating apparatus further includes a shower head positioned between the ion blocker and the treating space.

In an embodiment, the first gas supply unit supplies the process gas to a mixing space which is a space between the shower head and the ion blocker.

In an embodiment, the first gas supply unit includes a first gas line connected to a gas supply port formed at the ion blocker; and a second gas line connected to a gas inlet formed at the shower head.

In an embodiment, the gas supply port and the gas inlet are configured to supply the process gas to the mixing space.

In an embodiment, the gas supply port and the gas inlet are configured to supply the process gas to different regions of the mixing space.

In an embodiment, the gas supply port is configured to supply the process gas to a central region of the mixing space, and the gas inlet is configured to supply the process gas to an edge region of the mixing space.

In an embodiment, the gas inlet is configured to connect to the mixing space, but not connect to the treating space.

In an embodiment, the gas supply port is configured to connect to the mixing space, but not connect to the plasma space.

In an embodiment, the substrate treating apparatus further includes a controller, and wherein the controller controls the bottom power module, the top power module, and the gas supply unit to treat the substrate with any one mode among a first mode, a second mode, and a third mode, and wherein the first mode is a mode for generating the plasma at the plasma space, the second mode is a mode for generating the plasma at the plasma space and the treating space, and the third mode is a mode for generating the plasma at the treating space.

The inventive concept provides a substrate treating apparatus. The substrate treating apparatus includes a housing defining a treating space; an electrostatic chuck supporting a substrate at the treating space; a bottom electrode generating a plasma at the treating space; an ion blocker positioned above the housing; a top electrode positioned to face the ion blocker, the top electrode generating a plasma at a plasma space which is a space between the ion blocker and the top electrode, and the plasma space fluidly connecting with the treating space; a gas supply unit for supplying a process gas for exciting to a plasma state by the bottom electrode or the top electrode; a bottom power module for applying a power to the bottom electrode; and a top power module for applying a power to the top electrode.

In an embodiment, the substrate treating apparatus further includes a controller, and wherein the controller controls the bottom power module, the top power module, and the gas supply unit to treat the substrate with any one mode among a first mode, a second mode, and a third mode, and wherein the first mode is a mode for generating the plasma at the plasma space, the second mode is a mode for generating the plasma at the plasma space and treating space, and the third mode is mode for generating the plasma at the treating space.

In an embodiment, the controller controls the gas supply unit so the gas supply unit supplies at least one process gas among an 0, an H₂, an NF₃, an He, an Ar, and an NH₃, or combinations thereof during a treating of the substrate at the first mode.

In an embodiment, the controller controls the gas supply unit so the gas supply unit supplies at least one process gas among an Ar, an Xe, an NH₃, an H₂, an N₂, an O, an NF₃, an F₂, and an He, or combinations thereof during a treating of the substrate at the second mode.

In an embodiment, the controller controls the gas supply unit so the gas supply unit supplies at least one process gas among an He, an Ar, an Xe, an NH₃, an H₂, an N₂, an O, an NF₃, and an F₂, or combinations thereof during a treating of the substrate at the third mode.

The inventive concept provides a substrate treating apparatus for treating a substrate having a pattern formed thereon. The substrate treating apparatus includes a housing defining a treating space; an electrostatic chuck supporting the substrate at the treating space and providing a bottom electrode for generating a plasma at the treating space; a shower head positioned on top of the housing and defining the treating space; an ion blocker positioned above the housing and defining the mixing space together with the shower head; a top electrode positioned above the ion blocker, the top electrode defining the plasma space together with the ion blocker, and the top electrode generating a plasma at the plasma space; a first gas supply unit for supplying a process gas to the mixing space; and a second gas supply unit for supplying a process gas to the plasma space.

In an embodiment, the substrate treating apparatus further includes: a bottom power module for applying a power to the bottom electrode; a top power module for applying a power to the top electrode, and a controller, and wherein the controller controls the bottom power module, the top power module, the first gas supply unit, and the second gas supply unit to treat the substrate with any one mode among a first mode, a second mode, and a third mode according to a type of impurity remaining on the substrate, and wherein the first mode is a mode for generating the plasma at the plasma space, the second mode is a mode for generating the plasma at the plasma space and the treating space, and the third mode is a mode for generating the plasma at the treating space.

According to an embodiment of the inventive concept, a substrate may be efficiently treated.

According to an embodiment of the inventive concept, impurities attached to a substrate may be effectively removed.

According to an embodiment of the inventive concept, a removing efficiency of impurities attached to a substrate may be improved by differentiating a treating mode according to a type of the impurities attached to the substrate.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 illustrates a state of a substrate on which a treating process has been partially performed.

FIG. 2 illustrates a substrate treating apparatus according to an embodiment of the inventive concept.

FIG. 3 illustrates a treating mode which the substrate treating apparatus of FIG. 2 may select when treating the substrate.

FIG. 4 illustrates the substrate treating apparatus for performing a first radical process of a first mode of FIG. 3.

FIG. 5 illustrates the substrate treating apparatus for performing a second radical process of the first mode of FIG. 3.

FIG. 6 illustrates the substrate treating apparatus for performing an ion treatment process of a second mode of FIG. 3.

FIG. 7 illustrates a substrate on which the ion treatment process of FIG. 3 is performed.

FIG. 8 illustrates the substrate treating apparatus for performing a radical treatment process of the second mode of FIG. 3.

FIG. 9 illustrates a substrate on which the radical treatment process of FIG. 3 is performed.

FIG. 10 illustrates the substrate treating apparatus for performing an ion treatment process of a third mode of FIG. 3.

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises”, “comprising,”, “includes”, and/or “including” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “example” is intended to refer to an example or illustration.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

It should be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. Other terms such as “between”, “adjacent”, “near” or the like should be interpreted in the same way.

Unless otherwise defined, all terms used herein, including technical or scientific terms, have the same meaning as those generally understood by those skilled in the art to which the inventive concept belongs. Terms such as those defined in commonly used dictionaries should be interpreted as consistent with the context of the relevant technology and not as ideal or excessively formal unless clearly defined in this application.

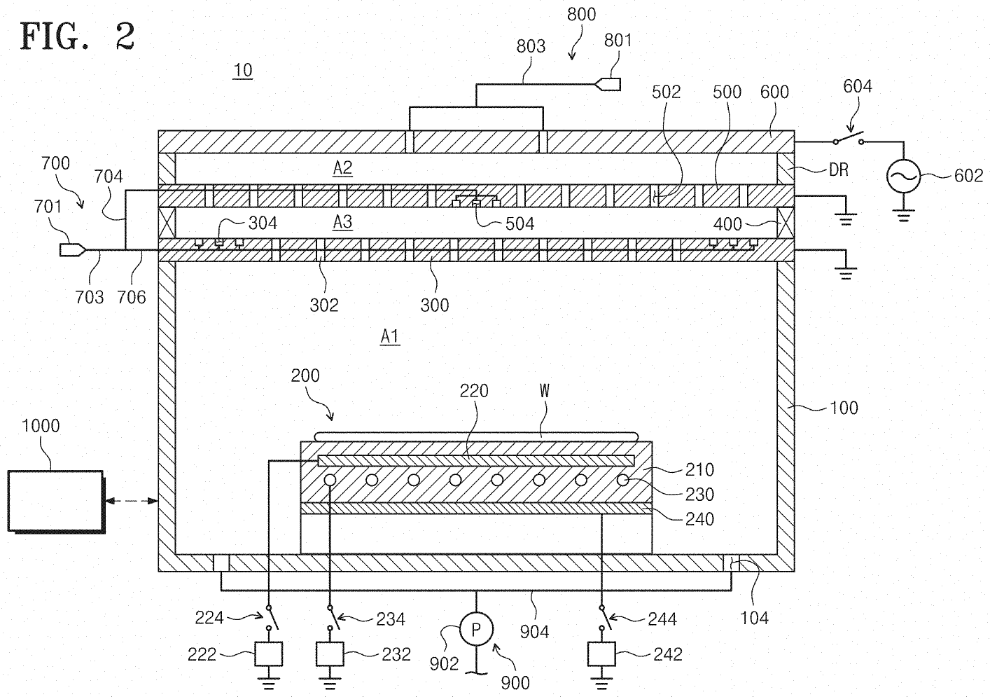

Hereinafter, an embodiment of the inventive concept will be described with reference to FIG. 2 to FIG. 10.

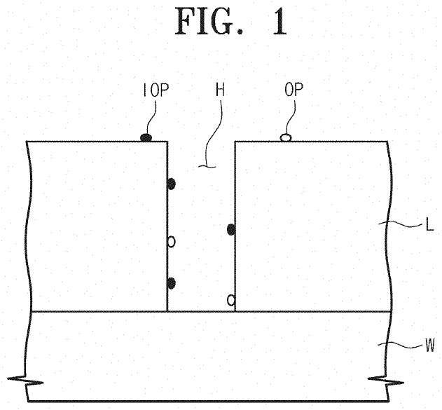

FIG. 2 schematically illustrates a substrate treating apparatus according to an embodiment of the inventive concept. Referring to FIG. 2, the substrate treating apparatus 10 according to an embodiment of the inventive concept may treat a substrate W. The substrate treating apparatus 10 may treat the substrate W using a plasma. The substrate treating apparatus 10 may remove impurities attached to the substrate W using the plasma. A substrate taken into the substrate treating apparatus W may be a substrate on which a treating process has been partially performed. For example, the substrate W taken into the substrate treating apparatus 10 may include a substrate W on which an etching process, a photolithography process, and the like have been performed. For example, a substrate W to be treated taken into the substrate treating apparatus 10 may be taken into the substrate treating apparatus 10 in the same or similar state as the substrate W described with reference to FIG. 1 (i.e., a state in which both the organic impurities OP and the inorganic impurities IOP are attached). On the other hand, only the organic impurities OP may be attached to the substrate W and taken into the substrate treating apparatus 10.

The substrate treating apparatus 10 may include a housing 100, a chuck 200, a shower head 300, a heating member 400, an ion blocker 500, an insulating member DR, a top electrode 600 (an exemplary second electrode), gas supply units 700 and 800, an exhaust unit 900, and a controller 1000.

The housing 100 and the shower head 300 may be combined with each other to define a treating space A1 (an exemplary first space) in which the substrate W is treated. Also, the shower head 300, the heating member 400, and the ion blocker 500 may be combined with each other to define a mixing space A3 (an exemplary third space) in which a plasma P in which an ion I has been removed and a first process gas G1 supplied by a first gas supply unit 700 is mixed. The ion blocker 500, the insulating member DR, and the top electrode 600 may be combined with each other to define a plasma space A2 (an exemplary second space) in which the plasma P is generated. Components involved in defining the treating space A1, the plasma space A2, and the mixing space A3 may be collectively referred to as a chamber.

The housing 100 may define the treating space A1. For example, the housing 100 in combination with the shower head 300 may define the treating space A1. The housing 100 may have a container shape with an open top. An inner wall of the housing 100 may be coated with a material capable of preventing the plasma P to be described later from etching the inner wall thereof. For example, the inner wall of the housing 100 may be coated with a dielectric film such as a ceramic. In addition, the housing 100 may be grounded. In addition, a door (not shown) may be installed in the housing 100 so that the substrate W may be brought into the treating space A1 or taken out of the treating space A1. The door may be selectively open and closed.

The chuck 200 may support the substrate W in the treating space A1. The chuck 200 may heat the substrate W. In addition, the chuck 200 may be an electrostatic chuck (ESC) capable of chucking the substrate W using an electrostatic force. The chuck 200 may include a support plate 210, an electrostatic electrode 220, a heater 230, and a bottom electrode (an exemplary first electrode).

The support plate 210 may support the substrate W. The support plate 210 may have a support surface supporting the substrate W. The support plate 210 may be provided as a dielectric. For example, the support plate 210 may be made of a ceramic material. The electrostatic electrode 220 may be provided in the support plate 210. The electrostatic electrode 220 may be provided at a position overlapping the substrate W when viewed from above. For example, a substantial portion of the electrostatic electrode 220 may overlap with the substrate W. When a power is applied to the electrostatic electrode 220, the electrostatic electrode 220 may form an electric field by an electrostatic force capable of chucking the substrate W. The resulting attractive force by the electric field may chuck the substrate W in a direction toward the support plate 210. Also, the electric field may make the ion I to be described later move (so, therefore, the ion I has an anisotropic state) in a forward direction toward the substrate W.

In addition, the substrate treating apparatus 10, for example, the chuck 200, may include first power modules 222 and 224 that apply the power to the electrostatic electrodes 220. The first power modules 222 and 224 may include an electrostatic electrode power source 222 and an electrostatic electrode switch 224. The power may be applied to the electrostatic electrode 220 according to an on/off of the electrostatic electrode switch 224.

The heater 230 may heat the substrate W. The heater 230 may heat the substrate W by increasing a temperature of the support plate 210. In addition, when the power is applied to the heater 230, the heater 230 may generate a heat. The heater 230 may be a heating element such as a tungsten. However, the type of the heater 230 is not limited thereto, and may be variously modified to a known heater. The heater 230 may increase the temperature of the support plate 210 to prevent by-products (for example, Si-polymer) separated from the substrate W while the substrate is being treated from being reattached to the hole H. For example, the heater 230 may control the temperature of the support plate 210 to 85° C. to 130° C.

In addition, the substrate treating apparatus 10, for example, the chuck 200, may include second power modules 232 and 234, which apply the power to the heater 230. The second power modules 232 and 234 may include a heater power source 232 and a heater power switch 234. The power may be applied to the heater 230 according to an on/off of the heater power switch 234.

The bottom electrode 240 may generate the plasma in the treating space A1. The bottom electrode 240 may have a plate shape. The bottom electrode 240 may be an electrode facing the shower head 300 to be described later. When a power is applied to the bottom electrode 240, the bottom electrode 240 forms the electric field in the treating space A1, and a formed electric field may generate the plasma P by exciting process gases G1 and G2 introduced (supplied) into the treating space A1. In addition, the substrate treating apparatus 10, for example, the chuck 200 may include bottom power supply modules 242 and 244 for applying the power to the bottom electrode 240. The bottom power modules 242 and 244 may include a bottom power source 242 which is an RF sources and a bottom power switch 244. The power may be applied to the bottom electrode 240 according to on/off of the bottom power switch 244.

The shower head 300 may be disposed on the top of the housing 100. The shower head 300 may be disposed between the ion blocker 500 to be described later and the treating space A1. The shower head 300 may be grounded. The shower head 300 may be grounded to function as an opposite electrode with the above-mentioned bottom electrode 240. In addition, a plurality of holes 302 may be formed at the shower head 300. The holes 302 may be formed to extend from a top surface to a bottom surface of the shower head 300. That is, the holes 302 may be formed through the shower head 300. The hole 302 may fluidly communicate the treating space A1 with the plasma space A2 to be described later. In addition, the hole 302 may fluidly communicate the treating space A1 with the mixing space A3 to be described later.

In addition, a gas inlet 304 may be formed at the shower head 300. The gas inlet 304 may be connected to a second gas line 706 to be described later. The gas inlet 304 may be configured to supply a first process gas G1 toward the mixing space A3. The gas inlet 304 may be configured to supply the process gas to an edge region of the mixing space A3. The gas inlet 304 may be configured to communicate with the mixing space A3 (also indirectly communicate with the plasma space A2), but not communicate with the treating space A1.

The heating member 400 may be disposed above the shower head 300. The heating member 400 may be a ring heater having a ring shape when viewed from above. The heating member 400 may generate a heat to increase a temperature of the mixing space A3 so that the plasma P from which an ion is removed and the first process gas G1 may be more effectively mixed.

The ion blocker 500 may separate the plasma space A2 and the mixing space A3 (further, indirectly separate the plasma space A2 and the treating space A1). The ion blocker 500 may be disposed between the top electrode 600 and the treating space A1.

The ion blocker 500 may be disposed on the top of the heating member 400. The ion blocker 500 may be grounded. The ion blocker 500 may be grounded to remove the ion I included in the plasma P, when the plasma P generated at the plasma space A2 flows into the mixing space A3, and further, the treating space A1. In short, since the plasma P generated at the plasma space A2 removes the ion I while going through the ion blocker 500, it may substantially include only the radical R.

In addition, the ion blocker 500 may be grounded and function as an electrode opposite to the top electrode 600 to be described later. A plurality of through holes 502 may be formed at the ion blocker 500. The through holes 502 may be formed through the ion blocker 500. The through holes 502 may fluidly communicate the plasma space A2 with the mixing space A3. The through holes 502 may fluidly communicate the plasma space A2 with the treating space A1.

In addition, a gas supply port 504 may be formed at the ion blocker 500. The gas supply port 504 may be connected to a first gas line 704 to be described later. The gas supply port 504 may be configured to supply a process gas to the mixing space A3. The gas supply port 504 may be configured to communicate with the mixing space A3 (also indirectly communicate with the treating space A1), but does not communicate with the plasma space A2.

The top electrode 600 may have a plate shape. The top electrode 600 may generate the plasma. The top power modules 602 and 604 included in the substrate treating apparatus 10 may apply a power to the top electrode 600. The top power modules 602 and 604 may include a top power source 602 which is an RF source and a top power switch 604. The power may be applied to the top electrode 600 according to an on/off of the top power switch 602. When the power is applied to the top electrode 600, an electric field is formed between the ion blocker 500 functioning as an opposite electrode and the top electrode 600, and thus a second process gas G2 may be excited to generated the plasma. In addition, the insulating member DR provided as an insulating material may be disposed between the top electrode 600 and the ion blocker 500. The insulating member DR may have a ring shape when viewed from above.

The gas supply units 700 and 800 may supply a process gas G1 and G2 for exciting into a plasma state P. The gas supply units 700 and 800 may include a first gas supply unit 700 and a second gas supply unit 800. Hereinafter, a gas supplied by the first gas supply unit 700 is referred to as a first process gas G1, and a gas supplied by the second gas supply unit 800 is referred to as a second process gas G2.

The first gas supply unit 700 may supply a process gas to the mixing space A3. The first gas supply unit 700 may supply a process gas to the treating space A1 by injecting the process gas to the mixing space A3. The first gas supply unit 700 may include a first gas supply source 701, a main gas line 703, a first gas line 704, and a second gas line 706. An end of the main gas line 703 may be connected to the first gas supply source 701, and another end of the main gas line 703 may branch to the first gas line 704 and the second gas line 706. The first gas line 704 may be connected to the gas supply port 504 of the ion blocker 500 described above. In addition, the second gas line 706 may be connected to the gas inlet 304 of the shower head 300 described above.

The first process gas G1 supplied by the first gas supply unit 700 may be at least one selected from a group consisting of an He, an Ar, an Xe, an NH₃, an H₂, an N₂, an O, an NF₃, and an F₂ or combinations thereof.

The second gas supply unit 800 may supply a process gas to the plasma space A2. The second gas supply unit 800 may supply the process gas to the plasma space A2 and the treating space A1 by injecting the process gas to the plasma space A2. The second gas supply unit 800 may include a second gas supply source 801 and gas channel 803. And end of the gas channel 803 may be connected to the second gas supply source 801, and the other end may be communicating with the plasma space A2.

The second process gas G2 supplied by the second gas supply unit 800 may be at least one of an an NF₃, an F₂, an He, an Ar, an Xe, an H₂, an N₂, or combinations thereof.

The exhaust unit 900 may discharge a process gas G1 and G2 suppled to the treating space A1, process by-products, and the like. The exhaust unit 900 may adjust a pressure of the treating space A1. The exhaust unit 900 may include a decompression member 902 and decompression line 904. The decompression member 902 may be a pump. However, the inventive concept is not limited thereto, and may be variously modified into a known device that provides a decompression.

The controller 1000 may control the substrate treating apparatus 10, specifically, components of the substrate treating apparatus 10. For example, the controller 1000 may control the gas supply units 700 and 800, the first power modules 222 and 224, the second power modules 232 and 234, the decompression member 902, the bottom power modules 242 and 244, and the top power modules 602 and 604. The controller may comprise a process controller consisting of a microprocessor (computer) that executes a control of the substrate treating apparatus, a user interface such as a keyboard via which an operator inputs commands to manage the substrate treating apparatus, and a display showing the operation situation of the substrate treating apparatus, and a memory unit storing a treating recipe, i.e., a control program to execute treating processes of the substrate treating apparatus by controlling the process controller or a program to execute components of the substrate treating apparatus according to data and treating conditions. In addition, the user interface and the memory unit may be connected to the process controller. The treating recipe may be stored in a storage medium of the storage unit, and the storage medium may be a hard disk, a portable disk, such as a CD-ROM or a DVD, or a semiconductor memory, such as a flash memory.

Hereinafter, a substrate treating method according to an embodiment of the inventive concept will be described. The substrate treating method described below may be performed by the substrate treating apparatus 10 described above. In addition, in order to perform the substrate treating method described below, the controller 1000 may control components of the substrate treating apparatus 10.

Hereinafter, a process gas supplied by a first gas supply unit 700 is referred to as a first process gas G1, and a process gas supplied by a second gas supply unit 800 is referred to as a second process gas G2. In addition, a plasma generated by a process gas excited in a treating space A1 is referred to as a first plasma P1, and a plasma generated by a process gas excited in a plasma space A2 is referred to as a second plasma P2. When the second plasma P2 generated at the plasma space A2 is introduced into the treating space A1, an ion is removed by an ion blocker 500, and thus the second plasma P2 may refer to a plasma from which the ion is removed. In addition, since the ion are not removed from the first plasma P1 generated at the treating space A1 by the ion blocker 500, the first plasma P1 may refer to a plasma including the ion.

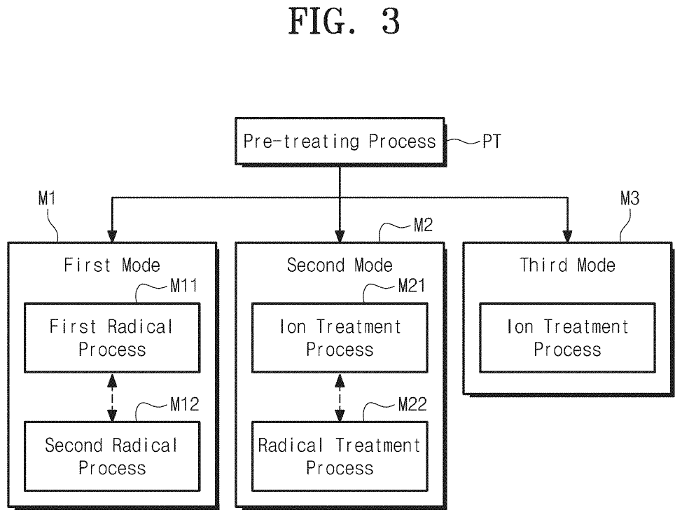

FIG. 3 illustrates a treating mode that may be chosen when the substrate treating apparatus of FIG. 2 treats a substrate. Referring to FIG. 3, a controller 1000 may select the treating mode of the substrate treating apparatus 10 according to a type of a preceding process PT. For example, the controller 1000 may control bottom power modules 242 and 244, top power modules 602 and 604 and gas supply units 700 and 800 of the substrate treating apparatus 10 to select any one among a first mode M1, a second mode M2, and a third mode M3 for the substrate treating apparatus 10 to treat the substrate W according to the type of the preceding process PT.

For example, if the preceding process PT is an etching process of etching the substrate W, both organic impurities OP and inorganic impurities TOP may be attached to the substrate W. Accordingly, when the preceding process PT is the etching process, the substrate treating apparatus 10 may treat the substrate W in the first mode M1 or the second mode M2 to be described later.

In contrast, when the preceding process PT is a photolithography process of treating the substrate W by supplying a photosensitive liquid and a developer, the organic impurities OP may be attached on the substrate W. Accordingly, when the preceding process PT is the photolithography process, the substrate treating apparatus 10 may treat the substrate W in the third mode M3 to be described later.

The first mode M1 may be a mode in which a first radical process M11 and a second radical process M12, which are processes in which a plasma is generated at a plasma space A2 and a plasma from which an ion is removed is transferred to the substrate to treat the substrate (i.e, a process of treating the substrate using radicals) is performed. The first radical process M11 and the second radical process M12 may be alternately and repeatedly performed. The first mode M1 may be a mode in which both the organic impurities and the inorganic impurities may be removed.

The second mode M2 may generate the plasma at the treating space A1 and transfer a plasma containing an ion to the substrate W to perform an ion treatment process M21 to treat the substrate W, and may generate the plasma at the plasma space A2 and transfer a plasma removed of an ion to the substrate to treat the substrate (i.e, a process of treating the substrate using radicals) to perform a radical treatment process M22. The ion treatment process M21 and the radical treatment process M22 may be alternately and repeatedly performed. The second mode M2 may be a mode in which both the organic impurities and the inorganic impurities may be removed.

In the third mode M3, only the ion treatment process, which is a process of generating the plasma at the treating space A1 and transferring the plasma containing an ion to the substrate W to treat the substrate W may be performed. The third mode M3 may be a mode in which the organic impurities may be removed.

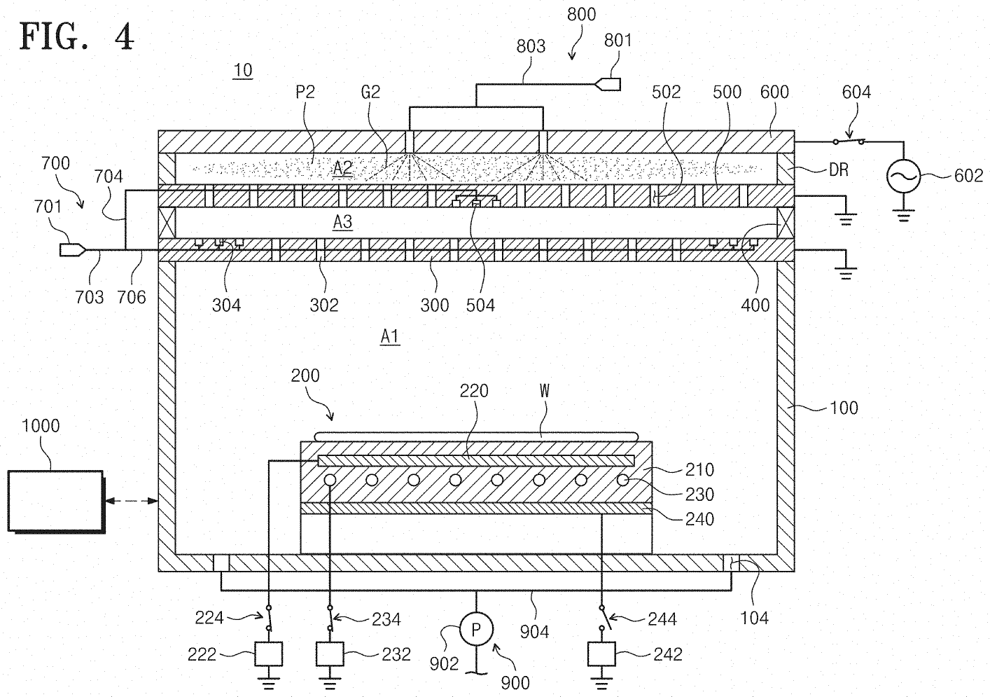

FIG. 4 illustrates a substrate treating apparatus for treating a substrate for performing a first radical process of a first mode of FIG. 3. Referring to FIG. 4, in the first radical process M11, a second gas supply unit 800 may supply a second process gas G2 to a plasma space A2. The second process gas G2 may include at least one of an H₂, an NH₃, an NF₃, an O, or combinations thereof and at least one of an He and an Ar, or combinations thereof. The top electrode 600 may form an electric field at the plasma space A2. The second plasma P2 generated at the plasma space A2 may flow through the ion blocker 500 to remove the ion I, and the second plasma P2 removed of an ion may be introduced into the treating space A1 and transferred to the substrate W.

If the second process gas G2 is a process gas including a hydrogen H, a carbon C on the substrate W may react with hydrogen radicals to be separated from the substrate W in a CH₄ form. If the second process gas G2 is a process gas including an oxygen O, the carbon C on the substrate W may react with the hydrogen radicals to be separated from the substrate W in a CO₂ form. If the second process gas G2 is a process gas including the hydrogen F, the carbon C on the substrate W may react with the hydrogen radicals to be separated from the substrate W in a CF₄ form. That is, the first radical process M11 may remove organic impurities OP on the substrate W.

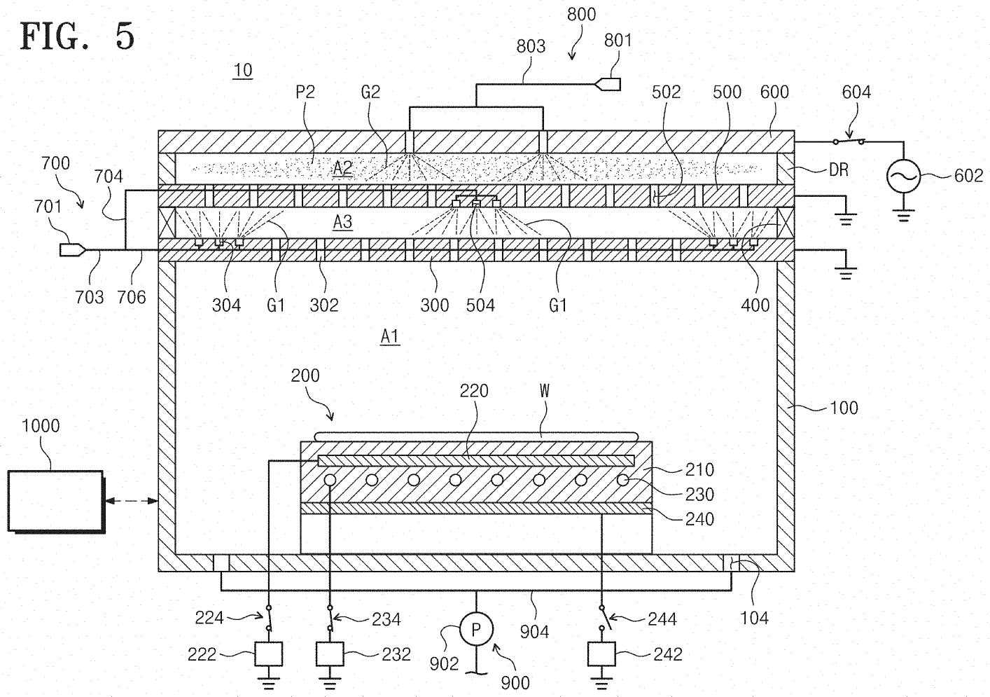

FIG. 5 illustrates a substrate treating apparatus for performing a second radical process of a first mode of FIG. 3. Referring to FIG. 5, in the second radical process M12, a first gas supply unit 700 may supply a first process gas G1 to a mixing space A3, and a second gas supply unit 800 may supply a second process gas G2 to a plasma space A2. A top electrode 600 may form an electric field at the plasma space A2.

The first process gas G1 may include an NH₃. The second process gas G2 may include at least one of an NF₃, an He, and an Ar, or combinations thereof. A second plasma P2 generated at the plasma space A2 may flow through an ion blocker 500 to remove an ion I, and a second plasma P2 from which the ion is removed may be mixed with the first process gas G1 at the mixing space A3. The second plasma P2 from which the ion is removed may be introduced into a treating space A1 while being mixed with the first process gas G1.

If the second process gas G2 includes an NF₃ and the first process gas G1 includes an NH₃, the second plasma P2 from which an ion is removed and the first process gas G1 may react with each other to generate an NH₄F. When the NH₄F flows into the treating space A1 and is transferred to the substrate W, an SiO₂, which are inorganic impurities IOP attached to the substrate, may react with the NH₄F to be separated from a (NH₄-)₂SiF₆ type substrate W.

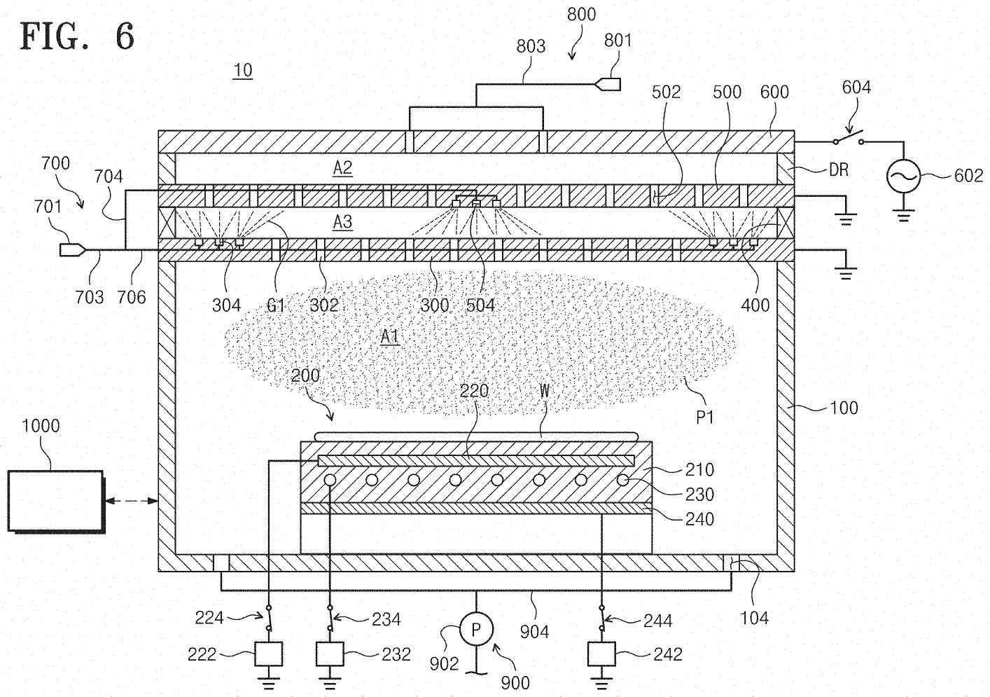

FIG. 6 illustrates a substrate treating apparatus for performing an ion treatment process of a second mode of FIG. 3. Referring to FIG. 6, in the ion treatment process M21, the first gas supply unit 700 may supply a first process gas G1 to a mixing space A3.

The first process gas G1 may include at least one of an He, an Ar, and an Xe, or combinations thereof and at least one of an NH₃, an H₂, an N₂, an O, an NF₃, and a F₂ or combinations thereof. When the first process gas G1 is introduced into a treating space A1, the first process gas G1 may be excited to a first plasma P1 by an electric field generated by a bottom electrode 240 at the treating space A1.

The first process gas G1 may include an NH₃. The second process gas G2 may include at least one of an NF₃, an He, and an Ar, or combinations thereof. The second plasma P2 generated at the plasma space A2 may flow through the ion blocker 500 to remove an ion I, and the second plasma P2 from which the ion is removed may be mixed with the first process gas G1 at the mixing space A3. The second plasma P2 from which the ion is removed may be introduced into the treating space A1 while being mixed with the first process gas G1.

When the second process gas G2 includes the NF₃ and the first process gas G1 includes the NH₃, the second plasma P2 from which the ion is removed and the first process gas G1 may react with each other to generate an NH₄F. When the NH₄F flows into the treating space A1 and is transferred to the substrate W, SiO₂, which is are inorganic impurities IOP attached to the substrate, may react with the NH₄F to be separated from an (NH₄-)₂SiF₆ type substrate W.

In addition, while the ion treatment process M21 is performed, the substrate W may be chucked by an electrostatic electrode 220. When a power is applied to the electrostatic electrode 220, an electric field generating a pulling force in a downward direction may be formed on the substrate W. Such an electric field may not only chuck the substrate W, but may also cause the ion I to be described later to have an anisotropic state (i.e., a state in which the ion I flows vertically in a downward direction).

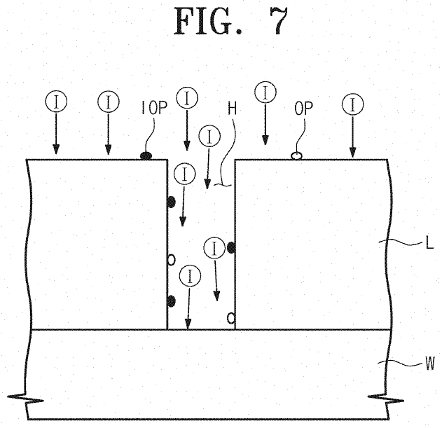

The first plasma P1 generated at the treating space A1 may include an ion I because it is directly generated at the treating space A1 without passing through an ion blocker 500. Since the ion I included in the first plasma P1 have a polarity, the ion I may have an anisotropy by an electrostatic force formed by the electrostatic electrode 220. Therefore, as illustrated in FIG. 7, the ion I may enter a hole H and be transferred to the organic impurities OP and/or the inorganic impurities TOP.

Since the impurities protrude from a film L, a hole H, and the substrate W, the inorganic impurities IOP may be relatively further treated by the ion I as compared to the film L, the hole H, and the substrate W. That is, a difference between a region treated by the ion I and a region not treated may cause a selection ratio difference.

In addition, when the first process gas G1 is a process gas including a hydrogen H, a carbon C on the substrate W may react with hydrogen radicals to be separated from the substrate W in a CH₄ form. When the first process gas G1 is a process gas including an oxygen O, the carbon C on the substrate W may react with hydrogen radicals to be separated from the substrate W in a CO₂ form. When the first process gas G1 includes the hydrogen F, the carbon C on the substrate W may react with hydrogen radicals to be separated from the substrate W in a CF₄ form. That is, the first radical process M11 may chemically remove the organic impurities OP on the substrate W.

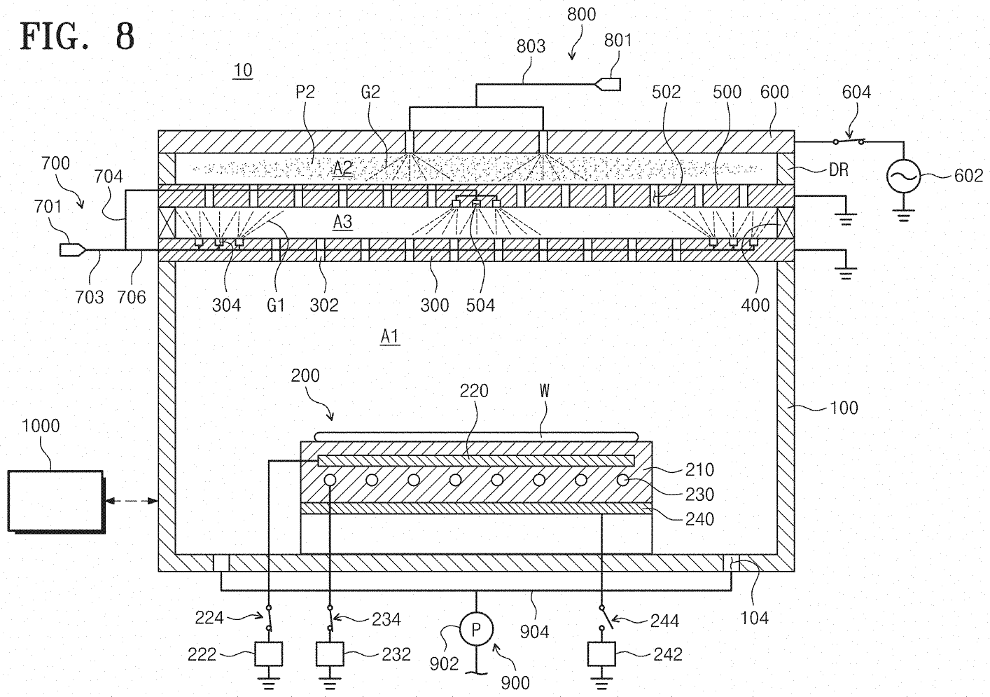

FIG. 8 illustrates a substrate treating apparatus for performing a radical treatment process of a second mode of FIG. 3.

In the radical treatment process M22, the first gas supply unit 700 may supply a first process gas G1 to a mixing space A3, and the second gas supply unit 800 may supply a second process gas G2 to a plasma space A2. A top electrode 600 may form an electric field at the plasma space A2.

The second process gas G2 may include at least one of an NF₃ and an F₂ or combinations thereof and at least one of an He, an Ar, an Xe, an H₂, and an N₂ or combinations thereof. In addition, the first process gas G1 may include at least one of an NF₃ and an F₂ or combinations thereof.

The second plasma P2 generated at the plasma space A2 may flow through the ion blocker 500 to remove the ions I, and the second plasma P2 from which the ions are removed may be mixed with the first process gas G1 in the mixing space A3. The second plasma P2 from which ions are removed may be introduced into the treating space A1 while being mixed with the first process gas G1.

When the second process gas G2 includes an NF₃ and the first process gas G1 includes an NH₃, the second plasma P2 from which ions are removed and the first process gas G1 may react with each other to generate an NH₄F. When the NH₄F flows into the treating space A1 and is transferred to the substrate W, an SiO₂, which are inorganic impurities IOP attached to the substrate, may react with the NH₄F to be separated from an (NH₄-)₂SiF₆ type substrate W.

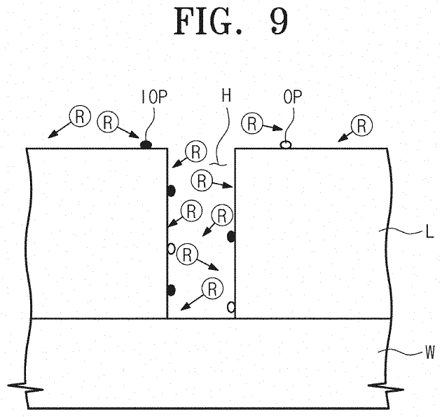

In addition, only a neutral radical R exists in the second plasma P2 from which an ion I is removed, and the radical R has isotropic properties. Accordingly, as shown in FIG. 9, inorganic impurities IOPs physically pre-treated with the ion I may be effectively removed.

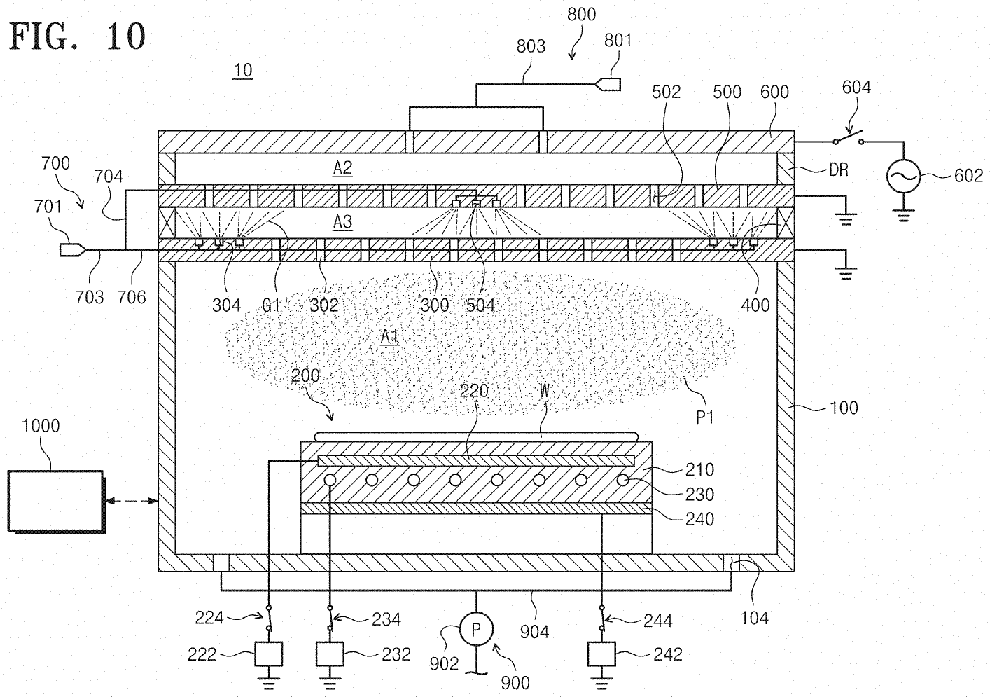

FIG. 10 illustrates a substrate treating apparatus for performing an ion treatment process of a third mode of FIG. 3. Referring to FIG. 10, in the third mode M3, the substrate treatment apparatus 10 may perform the ion treatment process. Since the ion treatment process may be the same as or similar to the ion treatment process M21 described above, repeated descriptions thereof will be omitted.

While a substrate W is treated with a first plasma P1 containing an ion I, a temperature of a chuck 200 may be controlled to 50° C. to 150° C., more preferably 85° C. to 130° C. In addition, while the substrate W is treated with the first plasma P1 including the ion I, a pressure of the treating space A1 may be controlled to be 5 mTorr to 150 mTorr, more preferably 10 mTorr to 100 mTorr, by the exhaust unit 900. In addition, during a first treating step S20, 50 W to 1500 W, more desirably 100 W to 1000 W, may be applied to a bottom electrode 240. In addition, while the substrate W is treated with the first plasma P1 including the ion I, a supplied process gas, for example, NH₃, may be supplied to the treating space A1 at 50 sccm to 1000 sccm, more desirably 100 sccm to 1000 sccm.

While treating the substrate with a second plasma P2 from which the ion I is removed, the temperature of the chuck 200 may be controlled to 50° C. to 150° C., more preferably 85° C. to 130° C. In addition, while the substrate is treated with the second plasma P2 from which the ion I is removed, the pressure of the treating space A1 may be controlled to 0.5 Torr to 15 Torr, more preferably 1 Torr to 10 Torr, by the exhaust unit 900. In addition, while the second treating step S40 is being performed, 20 W to 500 W, more desirably 50 W to 500 W, may be applied to a top electrode 600. In addition, a process gas, for example, a process gas including an NH₃, which is supplied during a treatment of the substrate with the second plasma P2 from which the ion I is removed, may be supplied to the mixing space A3 at 50 sccm to 1500 sccm, more preferably 100 sccm to 1000 sccm. In addition, while the substrate is treated with the second plasma P2 from which the ion I is removed, for example, the process gas including an NF₃ may be supplied to the plasma space A3 at 5 sccm to 800 sccm, more preferably 10 sccm to 500 sccm.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate treating apparatus comprising:
a housing defining a treating space;
a chuck supporting a substrate at the treating space and providing a bottom electrode for generating a plasma at the treating space;
a top electrode; and
an ion blocker positioned between the top electrode and the treating space.

2. The substrate treating apparatus of claim 1, wherein the ion blocker is grounded and removes an ion from the plasma generated at a plasma space which is a space between the top electrode and the ion blocker.

3. The substrate treating apparatus of claim 1, further comprising:
a bottom power module applying a power to the bottom electrode;
a top power module applying a power to the top electrode; and
a gas supply unit supplying a process gas for exciting to the plasma by the bottom electrode or the top electrode.

4. The substrate treating apparatus of claim 3, wherein the gas supply unit comprises:
a first gas supply unit for supplying the process gas to the treating space; and
a second gas supply unit for supplying the process gas to the plasma space which is a space between the ion blocker and the top electrode.

5. The substrate treating apparatus of claim 4, further comprising a shower head positioned between the ion blocker and the treating space.

6. The substrate treating apparatus of claim 5, wherein the first gas supply unit supplies the process gas to a mixing space which is a space between the shower head and the ion blocker.

7. The substrate treating apparatus of claim 6, wherein the first gas supply unit comprises:
a first gas line connected to a gas supply port formed at the ion blocker; and
a second gas line connected to a gas inlet formed at the shower head.

8. The substrate treating apparatus of claim 7, wherein the gas supply port and the gas inlet are configured to supply the process gas to the mixing space.

9. The substrate treating apparatus of claim 8, wherein the gas supply port and the gas inlet are configured to supply the process gas to different regions of the mixing space.

10. The substrate treating apparatus of claim 9, wherein the gas supply port is configured to supply the process gas to a central region of the mixing space, and the gas inlet is configured to supply the process gas to an edge region of the mixing space.

11. The substrate treating apparatus of claim 8, wherein the gas inlet is configured to connect to the mixing space, but not connect to the treating space.

12. The substrate treating apparatus of claim 8, wherein the gas supply port is configured to connect to the mixing space, but not connect to the plasma space.

13. The substrate treating apparatus of claim 8, further comprising a controller, and
wherein the controller configured to control the bottom power module, the top power module, and the gas supply unit to treat the substrate with any one mode among a first mode, a second mode, and a third mode, and
wherein the first mode is a mode for generating the plasma at the plasma space,
the second mode is a mode for generating the plasma at the plasma space and the treating space, and
the third mode is a mode for generating the plasma at the treating space.

14. A substrate treating apparatus comprising:
a housing defining a treating space;
an electrostatic chuck supporting a substrate at the treating space;
a bottom electrode generating a plasma at the treating space;
an ion blocker positioned above the housing;
a top electrode positioned to face the ion blocker, the top electrode generating a plasma at a plasma space which is a space between the ion blocker and the top electrode, and the plasma space fluidly connecting with the treating space;
a gas supply unit for supplying a process gas for exciting to a plasma state by the bottom electrode or the top electrode;
a bottom power module for applying a power to the bottom electrode; and
a top power module for applying a power to the top electrode.

15. The substrate treating apparatus of claim 14, further comprising a controller, and
wherein the controller configured to control the bottom power module, the top power module, and the gas supply unit to treat the substrate with any one mode among a first mode, a second mode, and a third mode, and
wherein the first mode is a mode for generating the plasma at the plasma space,
the second mode is a mode for generating the plasma at the plasma space and treating space, and
the third mode is mode for generating the plasma at the treating space.

16. The substrate treating apparatus of claim 15, wherein the controller configured to control the gas supply unit so the gas supply unit supplies at least one process gas among an 0, an H₂, an NF₃, an He, an Ar, and an NH₃, or combinations thereof during a treating of the substrate at the first mode.

17. The substrate treating apparatus of claim 15, wherein the controller configured to control the gas supply unit so the gas supply unit supplies at least one process gas among an Ar, an Xe, an NH₃, an H₂, an N₂, an O, an NF₃, an F₂, and an He, or combinations thereof during a treating of the substrate at the second mode.

18. The substrate treating apparatus of claim 15, wherein the controller configured to control the gas supply unit so the gas supply unit supplies at least one process gas among an He, an Ar, an Xe, an NH₃, an H₂, an N₂, an O, an NF₃, and an F₂, or combinations thereof during a treating of the substrate at the third mode.

19. A substrate treating apparatus for treating a substrate having a pattern formed thereon comprising:
a housing defining a treating space;
an electrostatic chuck supporting the substrate at the treating space and providing a bottom electrode for generating a plasma at the treating space;
a shower head positioned on top of the housing and defining the treating space;
an ion blocker positioned above the housing and defining the mixing space together with the shower head;
a top electrode positioned above the ion blocker, the top electrode defining the plasma space together with the ion blocker, and the top electrode generating a plasma at the plasma space;
a first gas supply unit for supplying a process gas to the mixing space; and
a second gas supply unit for supplying a process gas to the plasma space.

20. The substrate treating apparatus of claim 19 further comprising:
a bottom power module for applying a power to the bottom electrode;
a top power module for applying a power to the top electrode, and
a controller, and
wherein the controller configured to control the bottom power module, the top power module, the first gas supply unit, and the second gas supply unit to treat the substrate with any one mode among a first mode, a second mode, and a third mode according to a type of impurity remaining on the substrate, and
wherein the first mode is a mode for generating the plasma at the plasma space,
the second mode is a mode for generating the plasma at the plasma space and the treating space, and
the third mode is a mode for generating the plasma at the treating space.
